(19) United States
(12) Patent Application Publication
(10) Pub. No.: US 2026/0245595 A1
(43) Pub. Date: Aug. 20, 2026

(54) MEMORY DEVICE

(71) Applicant: Taiwan Semiconductor Manufacturing Company, Ltd., Hsinchu (TW)

(72) Inventors: Chia-En HUANG, Hsinchu (TW); Tzu-Chieh CHEN, Hsinchu (TW)

(73) Assignee: Taiwan Semiconductor Manufacturing Company, Ltd., Hsinchu (TW)

(21) Appl. No.: 19/056,280

(22) Filed: Feb. 18, 2025

(51) Int. Cl. G11C 5/06; G11C 8/08

(52) U.S. Cl. CPC G11C 5/063; G11C 8/08

(57) ABSTRACT

A memory device embodiment includes a front-end-of-line (FEOL) portion that includes a word line driver configured to output a word line signal to a first word line and a second word line, and a memory cell portion over the FEOL portion. The memory cell portion includes memory cells accessible as at least two memory cell arrays, including a first memory cell array that includes a first plurality of memory cells electrically coupled to the first word line, and a second memory cell array that includes a second plurality of memory cells electrically coupled to the second word line.

### BACKGROUND

Modern integrated circuit (IC) manufacturing technology enables faster, smaller, and more efficient devices. In many applications, the sizes of electrical components and transistors have shrunk to include more components in a semiconductor die, or even more layers of components in a semiconductor die. These advances in IC manufacturing technology have supported the development of a wide variety of digital devices, such as a memory device for storing data.

In some applications, a memory device corresponds to a semiconductor device that includes one or more semiconductor dies based on various configurations. In one example, a memory device is based on multiple memory dies stacked one over another within an IC package to enable high-density storage while minimizing the footprint. In another example, a memory device is based on a back-end-of-line (BEOL) memory configuration integrating memory cells and the corresponding driving and sensing circuitry in the same die.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a memory device, in accordance with some embodiments.

FIG. 2 is a cross-sectional view of a portion of a memory device, in accordance with some embodiments.

FIGS. 3A-3B are schematics of floorplans of a first memory device example, in accordance with some embodiments.

FIG. 4 is a schematic of a floorplan of a second memory device example, in accordance with some embodiments.

FIG. 5 is a schematic of a floorplan of a third memory device example, in accordance with some embodiments.

FIGS. 6A-6B are schematics of floorplans of a fourth memory device example and a fifth memory device example, in accordance with some embodiments.

FIGS. 7A-7B are block diagrams of memory device examples, in accordance with some embodiments.

FIG. 8 is a flowchart of a method of generating a layout plan for a semiconductor die, in accordance with some embodiments.

FIG. 9 is a flowchart of a method of manufacturing a semiconductor device, in accordance with some embodiments.

FIG. 10 is a block diagram of an electronic design automation (EDA) system in accordance with some embodiments.

FIG. 11 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “including” or “consisting of.” In this disclosure, the phrase “one of A, B, and C” means “A, B, and/or C” (A, B, C, A and B, A and C, B and C, or A, B and C), and does not mean one element from A, one element from B, and one element from C, unless otherwise described.

In some applications, a memory device is based on a configuration with memory cells accessible as one or more memory cell arrays over the corresponding control circuitry based on corresponding array base addresses. In some applications, different memory cell arrays correspond to different memory address spaces. In some applications, different memory cell arrays are physically separated by a gap in a semiconductor die, or in different semiconductor dies. In some applications, the controllers or controlling schemes for different memory cell arrays are fully independent or at least partially independent. In some applications, the one or more memory cell arrays and the control circuitry are within a same semiconductor die or in different semiconductor dies.

Based on one or more embodiments of the present disclosure, a word line driver is configured to output a word line signal to at least two word lines of different memory cell arrays (or to one functional word line and one dummy word line) in order to reduce and optimize the memory area efficiency and to balance the word line driving loading of different memory cell arrays. Based on one or more embodiments of the present disclosure, the at least two word lines are electrically coupled to memory cells of different memory cell arrays in two areas, and the word line driver is disposed in a driver area partially overlapping these two areas. In some applications, the benefits of a memory device based on the present disclosure may include relaxed front-end area and metallization resources, capability of sharing control schemes (e.g., a shared word line driver and/or decoder), additional resources for power mesh or signal paths for better operation speed, and/or balanced loading to mitigate the distance difference between near and far word lines.

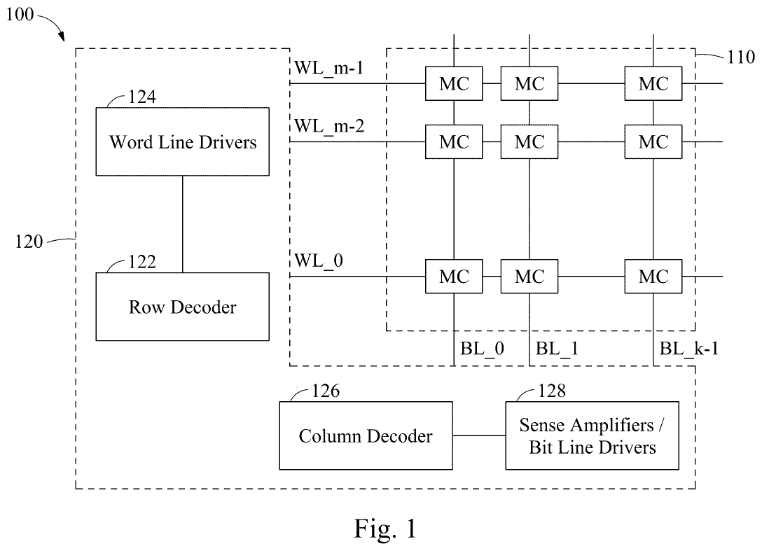

FIG. 1 is a block diagram of a memory device 100, in accordance with some embodiments. In some embodiments, memory device 100 is a non-limiting example, and various components of memory device 100 are simplified or omitted in FIG. 1. In some embodiments, memory device 100 is a standalone IC device or a part of an IC device together with other processing circuitry. In some embodiments, memory device 100 is based on one or more semiconductor dies.

In FIG. 1, memory device 100 includes a memory cell array 110 of memory cells (represented by rectangular blocks labeled “MC”) and control circuitry 120 configured to control an operation of memory cell array 110. In the example configuration in FIG. 1, the memory cells MC are arranged in columns and rows in memory cell array 110. The memory device 100 further includes a plurality of word lines WL_0 to WL_m-1 (or simply referred to as word lines, “WL”) electrically coupled to corresponding rows of memory cells, and a plurality of bit lines BL_0 to BL_k-1 (or simply referred to as bit lines, “BL”) electrically coupled to corresponding columns of memory cells. Each one of the memory cells MC is coupled to control circuitry 120 by at least one of the word lines and at least one of the bit lines. In some embodiments, each one of the memory cells MC is electrically coupled to control circuitry 120 by two word lines, including a read word line for read operations and a write word line for write operations. In some embodiments, each one of the memory cells MC is electrically coupled to control circuitry 120 by a single word line that is usable for read operations and/or for write operations. Moreover, in some embodiments, each one of the memory cells MC is further electrically coupled to control circuitry 120 by a single bit line or a pair of differential bit lines.

In FIG. 1, applicable word line configurations for each memory cell, including the single word line configuration and the double word line configuration discussed above, are simplified and collectively represented by a corresponding one of word lines WL_0 to WL_m-1. Also, in FIG. 1, applicable bit line configurations for each memory cell, including the single bit line configuration and the differential bit line configuration discussed above, are simplified and collectively represented by a corresponding one of bit lines BL_0 to BL_k-1. In some embodiments, the memory cells are further electrically coupled to control circuitry 120 through other type of signal lines extending along each one of the rows or each one of the columns, which are not shown in FIG. 1. Various numbers of word lines, bit lines, and/or other types of signal lines of the memory device 100 are within the scope of various embodiments.

In the example configuration in FIG. 1, control circuitry 120 includes a row decoder 122, a plurality of word line drivers 124, a column decoder 126, and a plurality of sense amplifiers and/or bit line drivers 128. In some embodiments, row decoder 122 interprets at least a portion of an address to be accessed during a read operation or a write operation, and selects one of word line drivers 124 to active one of the word lines that corresponds to the address. In some embodiments, the selected one of the word line drivers 124 activates a specific row (e.g., the corresponding word line) to enable access to the memory cells in the row. In some embodiments, column decoder 126 interprets at least another portion of the address and selects one of sense amplifiers and/or bit line drivers 128 coupled to one of the bit lines that corresponds to the address. In some embodiments, the selected one of sense amplifiers and/or bit line drivers 128 is configured to read the binary value stored in the memory cell specified by the decoded row and column via the corresponding bit line. In some embodiments, the selected one of sense amplifiers and/or bit line drivers 128 is configured to write the binary value to be stored in the memory cell specified by the decoded row and column via the corresponding bit line.

In some embodiments, control circuitry 120 further includes one or more clock generators for providing clock signals for various components of the memory device 100, one or more input/output (I/O) circuits for data exchange with external devices, and/or one or more control circuit blocks for controlling various operations in the memory device 100. In some embodiments, the configuration of memory device 100 is usable to implement a read-only memory device, a write-once memory device, an erasable memory device, a reprogrammable memory device, or a read-write memory device. In some embodiments, the memory cells MC correspond to volatile memory cells, such as dynamic random access memory (DRAM) cells or static random access memory (SRAM) cells. In some embodiments, the memory cells MC correspond to non-volatile memory cells, such as floating-gate memory cells, ferroelectric random access memory (FRAM) cells, magnetic random access memory (MRAM) cells, phase-change memory (PCM) cells, or resistive random access memory (RRAM) cells.

In FIG. 1, memory device 100 includes one memory cell array 110 as a non-limiting example. In some embodiments, a memory device includes memory cells arranged to be accessible as one or more memory cell arrays with the corresponding control circuitry.

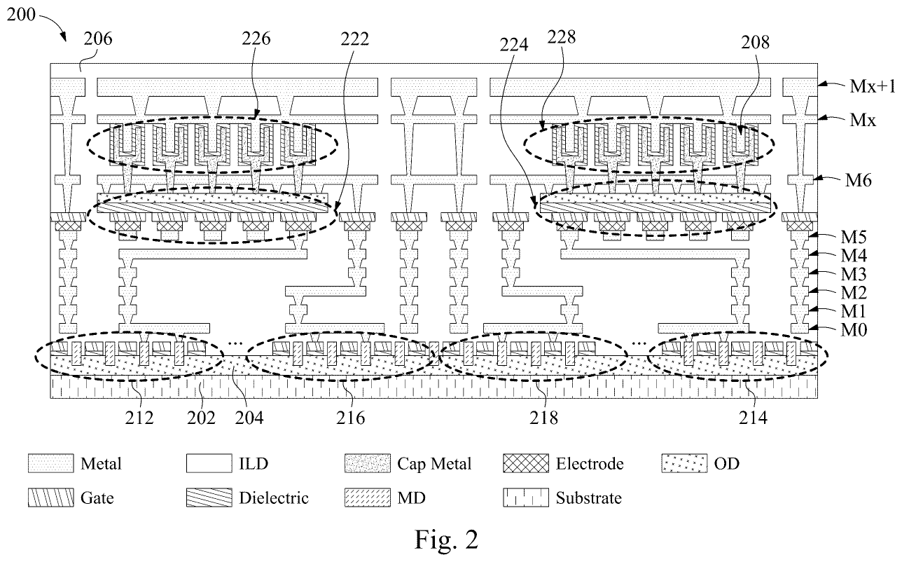

FIG. 2 is a cross-sectional view of a portion of a memory device 200, in accordance with some embodiments. In some embodiments, memory device 200 in FIG. 2 includes various components in a semiconductor die. In some embodiments, memory device 200 in FIG. 2 corresponds to a configuration illustrated by memory device 100 in FIG. 1. In some embodiments, the cross-sectional view in FIG. 2 is a simplified cross-sectional view, with many features simplified or not depicted.

In FIG. 2, memory device 200 includes a substrate 202 (corresponding to “Substrate” in the legend), an oxide diffusion (OD) layer 204 (corresponding to “OD” in the legend) over substrate 202, a plurality of metal-to-drain/source (MD) structures (corresponding to “MD” in the legend), a first set of gate dielectric structures (corresponding to “Dielectric” in the legend) over OD layer 204, and a first set of gate structures (corresponding to “Gate” in the legend) over the corresponding gate dielectric structures. In some embodiments, an OD structure corresponds to a structure usable as active regions for transitions. In some embodiments, an active region of a transistor corresponds to a doped region, where a channel, drain, and/or source of the transistor are formed based on such doped region. Memory device 200 also includes a plurality of metallization layers (e.g., M0, M1, M2, M3, M4, M5, M6, Mx, and Mx+1 layers, corresponding to “Metal” in the legend) and the corresponding via layers (not labeled, also corresponding to “Metal” in the legend) stacked one over another over the MD structures and/or the set of the gate structures. Moreover, memory device 200 includes a plurality of interlayer dielectric (ILD) layers (collectively labeled as “206” and corresponding to “ILD” in the legend).

In some embodiments, substrate 202 includes silicon, gallium arsenide, indium phosphide, silicon germanium, a combination thereof, or the like. In some embodiments, substrate 202 further includes one or more insulation layers. In some embodiments, OD layer 204 includes doped semiconductor materials suitable for forming channel structures of transistors. In some embodiments, the first set of gate structures includes tantalum nitride, titanium nitride, tungsten, aluminum, polysilicon, a combination thereof, or the like. In some embodiments, the first set of gate dielectric structures includes silicon dioxide. In some embodiments, the metallization layers and the corresponding via layers include a conductive material including copper, aluminum, gold, tungsten, a combination thereof, or the like. In some embodiments, ILD layers 206 include silicon dioxide.

In FIG. 2, as a non-limiting example, memory device 200 further includes a set of gate electrode structures (corresponding to “Electrode” in the legend) over M5 layer, a second set of gate structures (corresponding to “Gate” in the legend) over the set of gate electrode structures, a second set of gate dielectric structures (corresponding to “Dielectric” in the legend) over the second set of gate structures, and a set of OD structures (corresponding to “OD” in the legend) over the second set of gate dielectric structures. In FIG. 2, as a non-limiting example, memory device 200 further includes a set of capacitor metal structures (corresponding to “Cap Metal” in the legend) over the M6 layer and extending toward the Mx layer, a set of capacitor terminal structures (e.g., the structure 208, corresponding to “Metal” in the legend) extending from the Mx layer toward the M6 layer, and capacitor dielectric structures (also corresponding to “Dielectric” in the legend) between the set of capacitor metal structures and the set of capacitor terminal structures.

In some embodiments, the set of OD structures includes indium gallium zinc oxide, zinc oxide, indium oxide, tin dioxide, a combination thereof, or the like, for forming N-type channels. In some embodiments, the set of OD structures includes nickel oxide, cuprous oxide, copper aluminum oxide, copper gallium oxide, copper indium oxide, strontium copper oxide, tin oxide, a combination thereof, or the like, for forming P-type channels. In some embodiments, the second set of gate structures includes tantalum nitride, titanium nitride, tungsten, aluminum, polysilicon, a combination thereof, or the like. In some embodiments, the second set of gate dielectric structures includes hafnium oxide, silicon dioxide, aluminum oxide, silicon oxynitride, a combination thereof, or the like. In some embodiments, the set of capacitor metal structures includes tantalum nitride, titanium nitride, tungsten, aluminum, polysilicon, ruthenium, cobalt, copper, a combination thereof, or the like.

In some embodiments, memory device 200 further includes one or more redistribution layers and conductive pad structures (not in FIG. 2) over the one or more redistribution layers. In some embodiments, memory device 200 further includes conductive terminal structures (e.g., conductive bumps, copper pillar bumps, solder bumps, or the like, not in FIG. 2) over the conductive pad structures.

In FIG. 2, OD layer 204, MD structures, first set of gate dielectric structures, and first set of gate structures correspond to a front-end-of-line (FEOL) portion of memory device 200. In some embodiments, the FEOL portion of memory device 200 includes transistors formed based on OD layer 204, MD structures, first set of gate dielectric structures, and first set of gate structures, which are further configured to implement one or more word line drivers (e.g., word line drivers 212 and 214), one or more sense amplifiers (e.g., sense amplifiers 216 and 218), and/or other circuitry.

In FIG. 2, the set of gate electrode structures over the M5 layer, the second set of gate structures, the second set of gate dielectric structures, the set of OD structures, the set of capacitor metal structures over the M6 layer, the set of capacitor terminal structures from the Mx layer, and the capacitor dielectric structures correspond to a back-end-of-line (BEOL) portion of memory device 200. In some embodiments, the BEOL portion of memory device 200 includes transistors 222 and 224 formed based on the set of gate electrode structures over the M5 layer, the second set of gate structures, the second set of gate dielectric structures, and the set of OD structures. In some embodiments, the BEOL portion of memory device 200 further includes capacitors 226 and 228 formed based on the set of capacitor metal structures over the M6 layer, the set of capacitor terminal structures from the Mx layer, and the capacitor dielectric structures. In some embodiments, memory device 200 corresponds to a configuration having BEOL memory cells that are one-transistor, one-capacitor (1T1C) memory cells. In this example, transistors 222 and capacitors 226 constitute a first array of 1T1C memory cells, and transistors 224 and capacitors 228 constitute a second array of 1T1C memory cells. In this example, word line driver 212 is electrically coupled to a word line (e.g., at the M5 layer) of a row of the first memory cell array through the M0-M4 layers, and sense amplifier 216 is electrically coupled to a bit line (e.g., at the M6 layer) of a column of the first memory cell array through the M0-M5 layers. Also, word line driver 214 is electrically coupled to a word line (e.g., at the M5 layer) of a row of the second memory cell array through the M0-M4 layers, and sense amplifier 218 is electrically coupled to a bit line (e.g., at the M6 layer) of a column of the second memory cell array through the M0-M5 layers.

Memory device 200 in FIG. 2 corresponds to a configuration including control circuitry in the FEOL portion and two memory cell arrays in the BEOL portion. In some applications, memory device 200 is also referred to as having a circuit under array (CuA) configuration with 1T1C memory cells. In some embodiments, the memory cells in the BEOL portion correspond to magnetic tunnel junction memory cells, which include materials including iron mixed with cobalt, boron, nickel, magnesium oxide, a combination thereof, or the like. In some other embodiments, the memory cells in the BEOL portion or in another semiconductor die of the memory device correspond to volatile memory cells including DRAM cells or SRAM cells, or non-volatile memory cells including floating-gate memory cells, FRAM cells, MRAM cells, PCM cells, or RRAM cells.

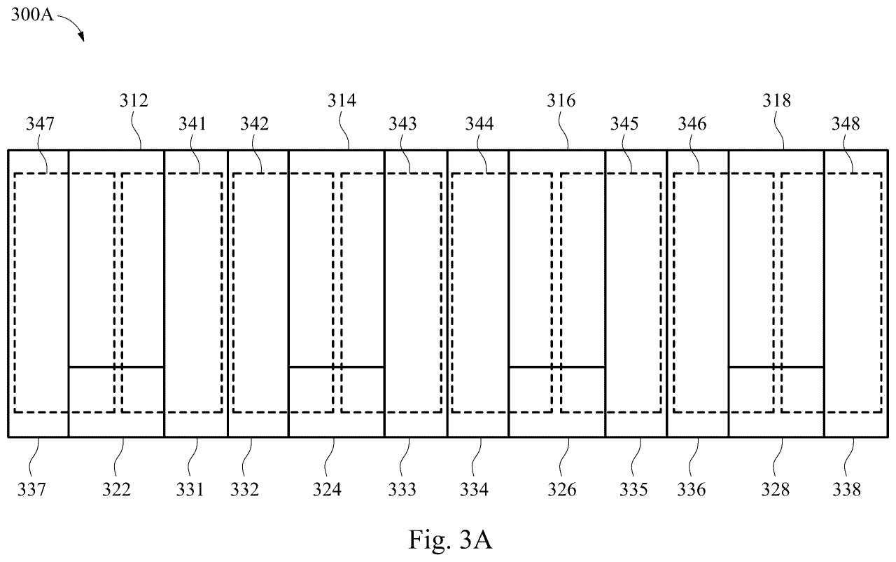

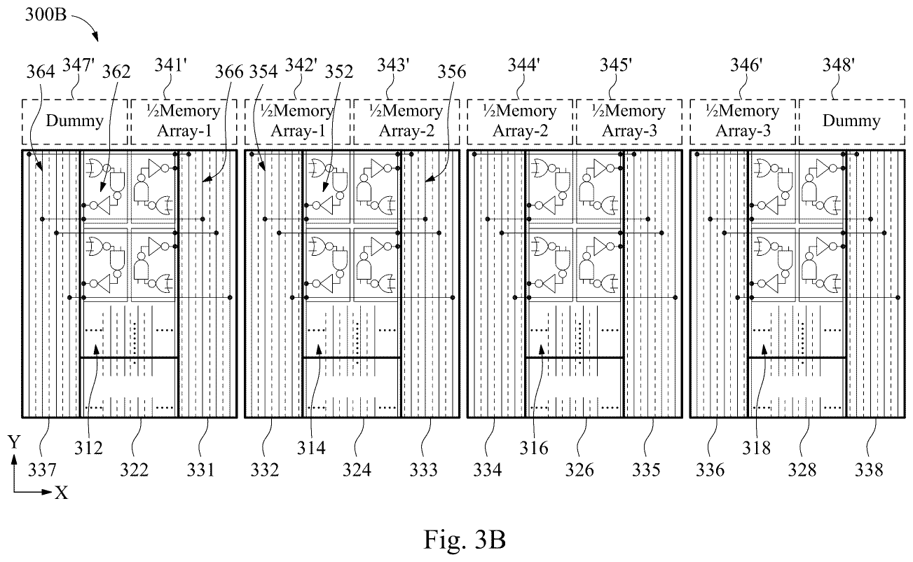

FIG. 3A is a schematic of a floorplan 300A of a first memory device example, in accordance with some embodiments. In some embodiments, floorplan 300A indicates the configuration of various electrical components of the first memory device example. The floorplan 300A indicates a FEOL portion of the first memory device example that includes word line driver areas 312, 314, 316, and 318 for word line drivers (e.g., word line drivers 124 in FIG. 1), decoder areas 322, 324, 326, and 328 for row decoders (e.g., row decoder 122 in FIG. 1) and column decoders (e.g., column decoder 126); sense amplifier areas 331, 332, 333, 334, 335, and 336 for sense amplifiers and/or bit line drivers (e.g., sense amplifiers and/or bit line drivers 128); and peripheral areas 337 and 338 for other circuitry. In FIG. 3A, floorplan 300A further indicates a memory cell portion of the first memory device example, which includes memory cell array areas 341, 342, 343, 344, 345, and 346 for memory cell arrays (e.g., memory cell array 110) disposed above the FEOL portion; and dummy areas 347 and 348 for dummy memory cells.

In FIG. 3A, memory cell area 341 and dummy area 347 are adjacent to each other and partially overlapping driver area 312; memory cell area 342 and memory cell area 343 are adjacent to each other and partially overlapping driver area 314; memory cell area 344 and memory cell area 345 are adjacent to each other and partially overlapping driver area 316; memory cell area 346 and dummy area 348 are adjacent to each other and partially overlapping driver area 318.

In some embodiments, the first memory device example includes three memory cell arrays that are separately accessible based on corresponding array base addresses. In FIG. 3A as a non-limiting example, memory cell array area 341 is for a first half of a first memory cell array, and memory cell array area 342 is for a second half of the first memory cell array; memory cell array area 343 is for a first half of a second memory cell array, and memory cell array area 344 is for a second half of the second memory cell array; and memory cell array area 345 is for a first half of a third memory cell array, and memory cell array area 346 is for a second half of the third memory cell array. In some embodiments as a non-limiting example, the memory cells in memory cell array areas 341, 342, 343, 344, 345, and 346 correspond to a BEOL portion of the first memory device example that is in the same semiconductor die as the FEOL portion of the first memory device example.

FIG. 3B is a schematic of another floorplan 300B of the first memory device example in FIG. 3A, in accordance with some embodiments. In some embodiments, floorplan 300B indicates the configuration of various word lines of the first memory device example in association with the FEOL portion and memory cell portion of the first memory device example. Components in FIG. 3B that are the same or similar to those in FIG. 3A are given the same reference numbers, and detailed description thereof is simplified or omitted.

In FIG. 3B, floorplan 300B includes tags 341′, 342′, 343′, 344′, 345′, 346′, 347′ and 348′ (respectively labeled “1/2 Memory Array-1”, “1/2 Memory Array-1”, “1/2 Memory Array-2”, “1/2 Memory Array-2”, “1/2 Memory Array-3”, “1/2 Memory Array-3”, “Dummy”, and “Dummy”) indicating memory cell array areas 341, 342, 343, 344, 345, and 346 and dummy areas 347 and 348 in FIG. 3A over the corresponding portions of floorplan 300B. The memory cell array areas 341, 342, 343, 344, 345, and 346 and dummy areas 347 and 348 are not shown in FIG. 3B to avoid obscuring the illustration of word drivers and word lines.

In FIG. 3B, floorplan 300B includes bold solid blocks indicating various areas, including word line driver areas 312, 314, 316, and 318; decoder areas 322, 324, 326, and 328; sense amplifier areas 331, 332, 333, 334, 335, and 336; and peripheral areas 337 and 338. In FIG. 3B, fine solid lines extending along the Y direction represent word lines (regardless of being functional or dummy word lines) at a metallization layer for word lines (e.g., the M5 layer in FIG. 2). Also, in FIG. 3B, fine dashed lines extending along the Y direction represent other signal lines or power mesh at metallization layer for word lines. In FIG. 3B, fine solid lines extending along the X direction across multiple areas represent conductive lines at one or more metallization layers different from the metallization layer for word lines for electrically coupling word line drivers and word lines.

In FIG. 3B, each word line driver in a word line driver area is configured to output a word line signal to two word lines of two different memory cell arrays in adjacent areas that partially overlap the word line driver area. In some embodiments, the location of the word lines in association with the word line drivers are arranged such that the loadings observable at the word line drivers are about the same regardless of the location of the word lines. In some embodiments, the logic gates of the word line drivers in FIG. 3B are used as non-limiting examples and do not dictate the actual circuitry or configuration of the word line drivers.

For example, in a region corresponding to areas 314, 324, 332, and 333 with memory cell array areas 342 and 343 (as indicated by tags 342′ and 344′), a word line driver 352 in word line driver area 314 is configured to output a word line signal to a word line 354 in memory cell area 342 and a word line 356 in memory cell area 343. In this example, the first memory cell array includes a plurality of memory cells (e.g., in the second half of the first memory cell array in the area indicated by tag 342′) electrically coupled to word line 354, and the second memory cell array includes a plurality of memory cells (e.g., in the first half of the second memory cell array in the area indicated by tag 343′) electrically coupled to word line 356. In some embodiments, the configuration in the region corresponding to areas 316, 326, 334, and 335 with memory cell array areas 344 and 345 is similar to the configuration illustrated above.

Also, in a region corresponding to areas 312, 322, 331, and 337 with memory cell array area 341 and dummy area 347 (as indicated by tags 341′ and 347′), a word line driver 362 in word line driver area 312 is configured to output a word line signal to a word line 364 in dummy area 347 and a word line 366 in memory cell area 341. In this example, the first memory cell array includes a plurality of memory cells (e.g., in the first half of the first memory cell array in the area indicated by tag 341′) electrically coupled to word line 366. In this example, word line 364 is configured as a dummy word line that is not electrically coupled to any functional memory cells. In some embodiments, the configuration in the region corresponding to areas 318, 328, 336, and 338 with memory cell array area 346 and dummy area 348 is similar to the configuration illustrated above.

Accordingly, a memory device based on the example in FIG. 3B includes a FEOL portion that includes a word line driver (e.g., word line driver 352) configured to output a word line signal to a first word line (e.g., word line 354) and a second word line (e.g., word line 356). The memory device based on the example in FIG. 3B further includes a memory cell portion over the FEOL portion, where the memory cell portion includes a first memory cell array (e.g., the second half of the first memory cell array in the area indicated by tag 342′) that includes a first plurality of memory cells electrically coupled to the first word line, and a second memory cell array (e.g., the first half of the second memory cell array in the area indicated by tag 343′) that includes a second plurality of memory cells electrically coupled to the second word line. In some embodiments, the FEOL portion included in the memory device based on the example in FIG. 3B further includes a first plurality of sense amplifiers electrically coupled to a first plurality of bit lines (e.g., in sense amplifier area 332 in view of the examples in FIGS. 1 and 2) and a second plurality of sense amplifiers electrically coupled to a second plurality of bit lines (e.g., in sense amplifier area 333 in view of the examples in FIGS. 1 and 2). In some embodiments, the first plurality of memory cells is electrically coupled to corresponding ones of the first plurality of bit lines. In some embodiments, the second plurality of memory cells is electrically coupled to corresponding ones of the second plurality of bit lines.

In some embodiments, the FEOL portion included in the memory device based on the example in FIG. 3B further includes a second word line driver (e.g., word line driver 362) configured to output a second word line signal to a third word line (e.g., word line 366) and a third plurality of sense amplifiers electrically coupled to a third plurality of bit lines (e.g., in sense amplifier area 331 in view of the examples in FIGS. 1 and 2). In some embodiments, the first memory cell array further includes a third plurality of memory cells (e.g., the first half of the first memory cell array in the area indicated by tag 341′) electrically coupled to the third word line and corresponding ones of the third plurality of bit lines. In some embodiments, the second word line driver is configured to output the second word line signal further to a dummy word line (e.g., word line 364).

Based on the arrangement of word line drivers and word lines as illustrated in FIG. 3B, the balance of loading of the word line drivers of the first memory device example is improved. Also, a portion of the word line drivers is shared by two different memory cell arrays, which further reduces the number of word line drivers required, reduces or simplifies the row decoders, reduces the physical area the word line drivers occupy, and/or allows an increase of the driving capability within the same physical area. In some embodiments, based on the arrangement of word line drivers and word lines as illustrated in FIG. 3B, the physical area of the FEOL portion and the routing for the metallization layers are relaxed, which provides the flexibility for a more compact layout, or added power mesh or widened signal lines for better driving speed.

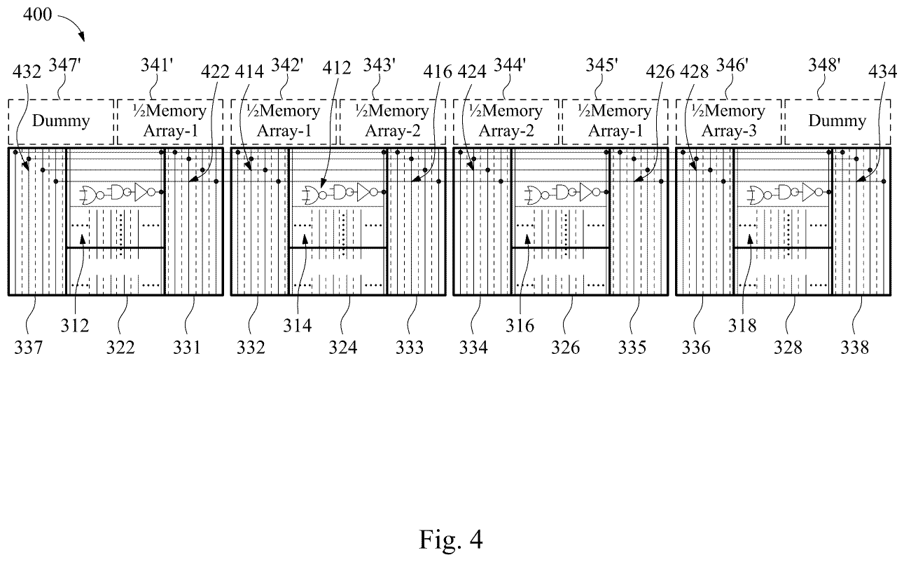

FIG. 4 is a schematic of a floorplan 400 of a second memory device example, in accordance with some embodiments. In some embodiments, floorplan 400 indicates the configuration of various word lines of the second memory device example in association with the FEOL portion and memory cell portion of the second memory device example. In some embodiments, the second memory device example is a variation of the first memory device example in FIGS. 3A-3B. Components in FIG. 4 that are the same or similar to those in FIG. 3B are given the same reference numbers, and detailed description thereof is simplified or omitted.

Based on the example in FIG. 3B, each word line driver is configured to output a word line signal to two word lines of two half memory arrays of different memory cell arrays (or one word line for one memory cell array and the other word line being a dummy word line). In FIG. 4, each word line driver (e.g., word line driver 412) based on floorplan 400 is configured to output a word line signal to the word lines of all half memory arrays (e.g., word lines 414, 416, 422, 424, 426, and 428 of half memory arrays in the areas indicated by tags 342′, 343′, 341′, 344′, 345′, and 346′). In some embodiments, each word line driver (e.g., word line driver 412) is further configured to output the word line to dummy word lines (e.g., word lines 432 and 434) of dummy areas (e.g., indicated by tags 347′ and 348′).

Accordingly, compared to the example in FIG. 3B, a word line driver included in a memory device based on the example in FIG. 4 is configured to output a word line signal further to not only a first word line and a second word line associated with the memory cell arrays in the areas overlapping the word line driver, but also at least another word line associated with at least another memory cell array. In some embodiments, the FEOL portion included in the memory device based on the example in FIG. 4 includes another plurality of sense amplifiers electrically coupled to another plurality of bit lines. In some embodiments, the memory cell portion included in the memory device based on the example in FIG. 4 includes the another memory cell array that includes another plurality of memory cells electrically coupled to the another word line and corresponding ones of the another plurality of bit lines. In some embodiments, a memory device based on the arrangement of word line drivers and word lines as illustrated in FIG. 4 also includes one or more improvements as discussed above with respect to a memory device based on the arrangement of word line drivers and word lines as illustrated in FIG. 3B.

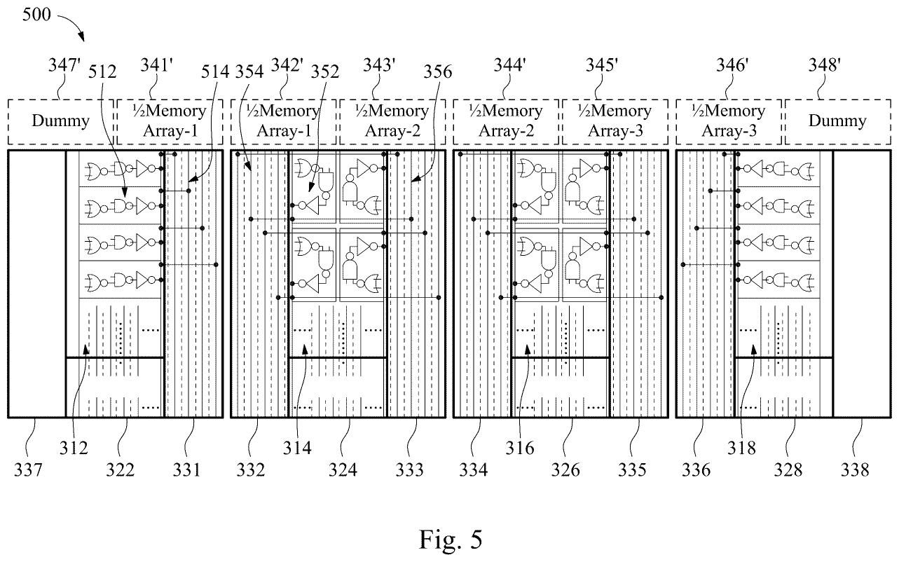

FIG. 5 is a schematic of a floorplan 500 of a third memory device example, in accordance with some embodiments. In some embodiments, floorplan 500 indicates the configuration of various word lines of the third memory device example in association with the FEOL portion and memory cell portion of the third memory device example. In some embodiments, the third memory device example is a variation of the first memory device example in FIGS. 3A-3B. Components in FIG. 5 that are the same or similar to those in FIG. 3B are given the same reference numbers, and detailed description thereof is simplified or omitted.

In FIG. 5, floorplan 500 includes a center portion including areas 314, 324, 332, 333, 316, 326, 334, and 335. In the center portion, each one of word line driver areas 314 and 316 between corresponding sense amplifier areas 332/333 or 334/335 overlaps two half memory arrays of two different memory cell arrays (e.g., in the areas indicated by tags 342′/343′ or 344′ and 345′). Also, floorplan 500 includes edge portions including areas 312, 322, 331, 337, 318, 328, 336 and 338. In the edge portions, each one of word line driver areas 312 and 318 between a corresponding sense amplifier area 331 or 336 and a corresponding peripheral area 337 or 338 overlaps one half memory array (e.g., in the areas indicated by tags 341′ or 346′) and a dummy area (e.g., indicated by tags 347′ or 348′).

In some embodiments and as shown in FIG. 5, the word line driver in the edge portions (e.g., word line driver 512) is configured to output a word line signal to one word line (e.g., word line 514) associated with the corresponding half memory arrays (e.g., in the area indicated by tag 341′). In some embodiments and as shown in FIG. 5, the word line driver in the center portion (e.g., word line driver 352) is configured to output a word line signal to two word lines associated with the two corresponding half memory arrays (e.g., in the areas indicated by tags 342′/343′) in view of the example in FIG. 3B. In some other embodiments, the word line driver in the center portion is configured to output a word line signal to all word lines associated with all half memory arrays in the center portion in view of the example in FIG. 4. In some embodiments, a memory device based on the arrangement of word line drivers and word lines as illustrated in FIG. 5 also includes one or more improvements as discussed above with respect to a memory device based on the arrangement of word line drivers and word lines as illustrated in FIG. 3B.

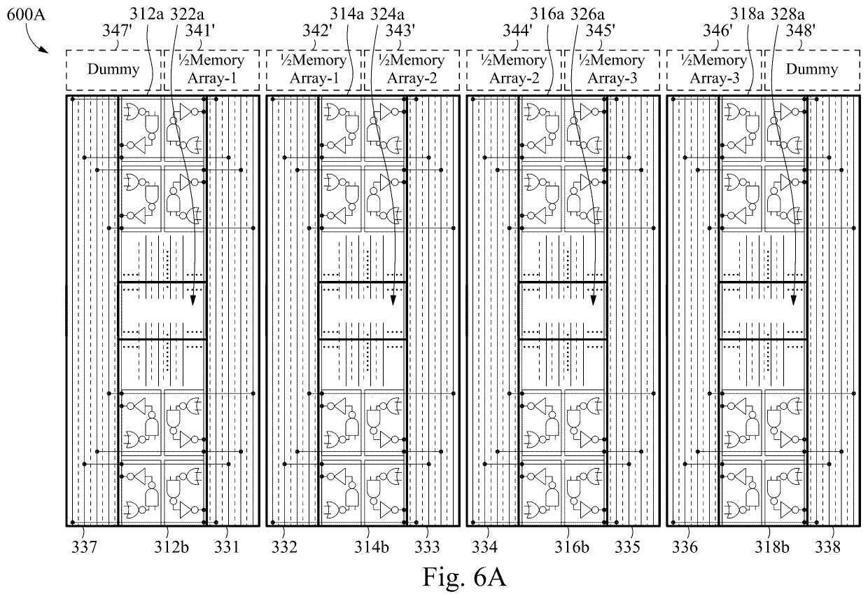

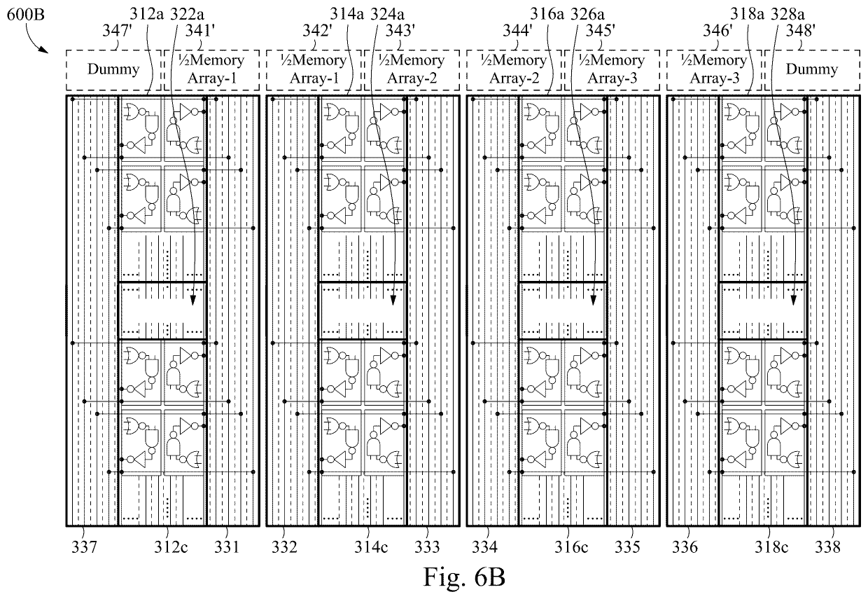

FIG. 6A is a schematic of a floorplan 600A of a fourth memory device example, in accordance with some embodiments. In some embodiments, floorplan 600A indicates the configuration of various word lines of the fourth memory device example in association with the FEOL portion and memory cell portion of the fourth memory device example. In some embodiments, the fourth memory device example is a variation of the first memory device example in FIGS. 3A-3B. Components in FIG. 6A that are the same or similar to those in FIG. 3B are given the same reference numbers, and detailed description thereof is simplified or omitted.

Compared to the first memory device example in FIG. 3A, the fourth memory device example in FIG. 6A rearranged word line driver areas 312, 314, 316, and 318 and decoder areas 322, 324, 326, and 328 in floorplan 300B into word line driver areas 312a, 312b, 314a, 314b, 316a, 316b, 318a, and 318b and decoder areas 322a, 324a, 326a, and 328a. In this example, each word line driver area in floorplan 300B is divided into two word line driver areas in floorplan 600A that are positioned at the upper portion and the lower portion of floorplan 600A. In this example, word line driver areas in floorplan 300B are rearranged from the lower portion of floorplan 300B to be between the corresponding word line driver areas in floorplan 600A.

Moreover, in this example, each one of the word line drivers (and the corresponding word lines) in floorplan 300B is replaced with two word line drivers (and the corresponding word lines) in floorplan 600A that are symmetrically positioned in the corresponding word line driver areas 312a/312b, 314a/314b, 316a/316b, and 318a/318b with respect to the decoder areas 322a, 324a, 326a, and 328a. In this example, the fourth memory device example in FIG. 6A is illustrated as a non-limiting example of modifying the arrangement of the word line drivers and the corresponding word lines. In some embodiments, the word line drivers and the corresponding word lines in the second memory device example in FIG. 4 and the third memory device example in FIG. 5 are also modifiable in a manner similar to the example illustrated in FIG. 6A.

FIG. 6B is a schematic of a floorplan 600B of a fifth memory device example, in accordance with some embodiments. In some embodiments, floorplan 600B indicates the configuration of various word lines of the fifth memory device example in association with the FEOL portion and memory cell portion of the fifth memory device example. In some embodiments, the fifth memory device example is a variation of the fourth memory device example in FIG. 6A. Components in FIG. 6B that are the same or similar to those in FIG. 6A and FIG. 3B are given the same reference numbers, and detailed description thereof is simplified or omitted.

Compared to the first memory device example in FIG. 3A, the fifth memory device example in FIG. 6B rearranged word line driver areas 312, 314, 316, and 318 and decoder areas 322, 324, 326, and 328 in floorplan 300B into word line driver areas 312a, 312c, 314a, 314c, 316a, 316c, 318a, and 318c and decoder areas 322a, 324a, 326a, and 328a. In this example, each word line driver area in floorplan 300B is divided into two word line driver areas in floorplan 600B that are positioned at the upper portion and the lower portion of floorplan 600B. In this example, word line driver areas in floorplan 300B are rearranged from the lower portion of floorplan 300B to be between the corresponding word line driver areas in floorplan 600B.

Moreover, in this example, each one of the word line drivers (and the corresponding word lines) in floorplan 300B is replaced with two word line drivers (and the corresponding word lines) in floorplan 600B that are sequentially positioned based on the same spatial sequence in the corresponding word line driver areas 312a, 312c, 314a, 314c, 316a, 316c, 318a, and 318c. In this example, the fifth memory device example in FIG. 6B is illustrated as a non-limiting example of modifying the arrangement of the word line drivers and the corresponding word lines. In some embodiments, the word line drivers and the corresponding word lines in the second memory device example in FIG. 4 and the third memory device example in FIG. 5 are also modifiable in a manner similar to the example illustrated in FIG. 6B.

In some embodiments, a memory device based on the arrangement of word line drivers and word lines as illustrated in FIG. 6A or FIG. 6B also includes one or more improvements as discussed above with respect to a memory device based on the arrangement of word line drivers and word lines as illustrated in FIG. 3B.

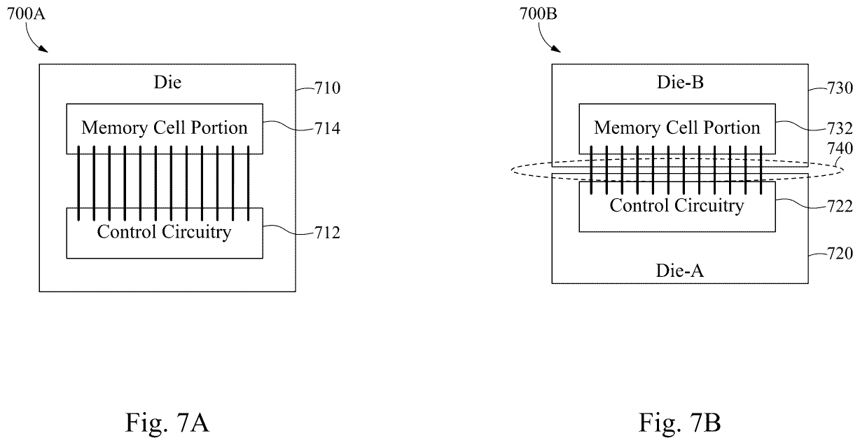

FIG. 7A is a block diagram of a memory device example 700A, in accordance with some embodiments. In this example, memory device example 700A corresponds to a semiconductor device that includes a semiconductor die 710. In this example, semiconductor die 710 includes control circuitry 712 (e.g., control circuitry 120 in FIG. 1, or word line drivers 212 and 214 and sense amplifiers 216 and 218 in FIG. 2, or circuit blocks in word line driver areas 312, 314, 316, and 318, decoder areas 322, 324, 326, and 328, and sense amplifier areas 331, 332, 333, 334, 335, and 336 in FIGS. 3A-5) in the FEOL portion of semiconductor die 710. In this example, semiconductor die 710 further includes memory cell portion 714 (e.g., memory cell array 110 in FIG. 1, or transistors 222 and 224 and capacitors 226 and 228 in FIG. 2, or memory cells in memory cell array areas 341, 342, 343, 344, 345, and 346 in FIG. 3A) in the BEOL portion of semiconductor die 710.

FIG. 7B is a block diagram of another memory device example 700B, in accordance with some embodiments. In this example, memory device example 700B corresponds to a semiconductor device that includes two semiconductor dies 720 (labeled “Die-A”) and 730 (labeled “Die-B”) and signal paths 740 (e.g., represented by solid lines and correspond to at least conductive terminals such as micro bumps, solder bumps, or copper pillar bumps) connecting semiconductor dies 720 and 730. In this example, semiconductor die 720 includes control circuitry 722 (e.g., control circuitry 120 in FIG. 1, or word line drivers 212 and 214 and sense amplifiers 216 and 218 in FIG. 2, or circuit blocks in word line driver areas 312, 314, 316, and 318, decoder areas 322, 324, 326, and 328, and sense amplifier areas 331, 332, 333, 334, 335, and 336 in FIGS. 3A-5) in the FEOL portion of semiconductor die 720. In this example, semiconductor die 730 includes memory cell portion 732 (e.g., memory cell array 110 in FIG. 1, or transistors 222 and 224 and capacitors 226 and 228 in FIG. 2, or memory cells in memory cell array areas 341, 342, 343, 344, 345, and 346 in FIG. 3A) in the FEOL portion and/or BEOL portion of semiconductor die 730. In some embodiments, the word lines and bit lines associated with memory cell portion 732 are included in semiconductor dies 730 and electrically coupled to control circuitry 722 through signal paths 740.

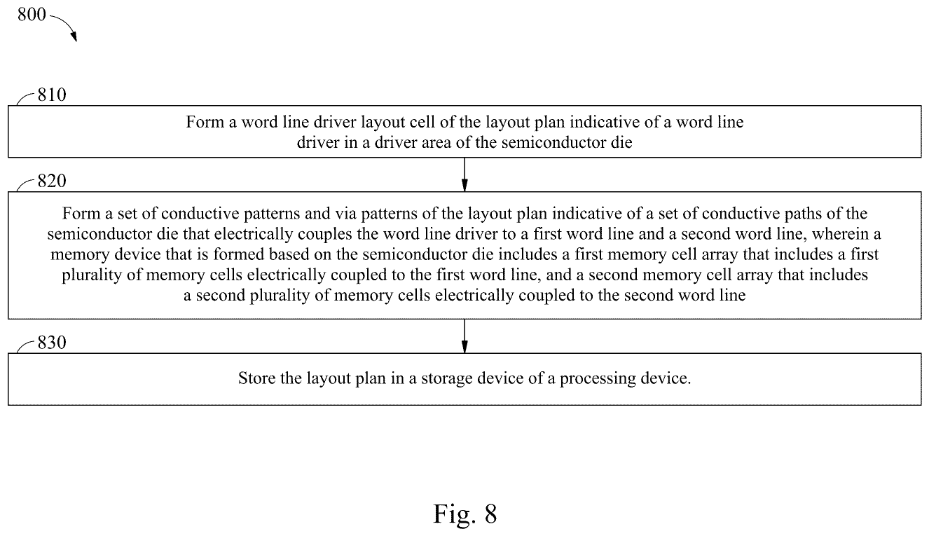

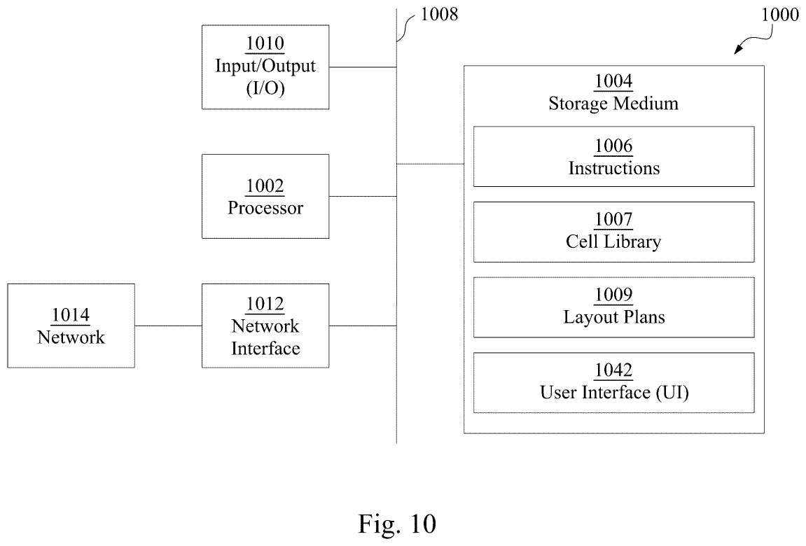

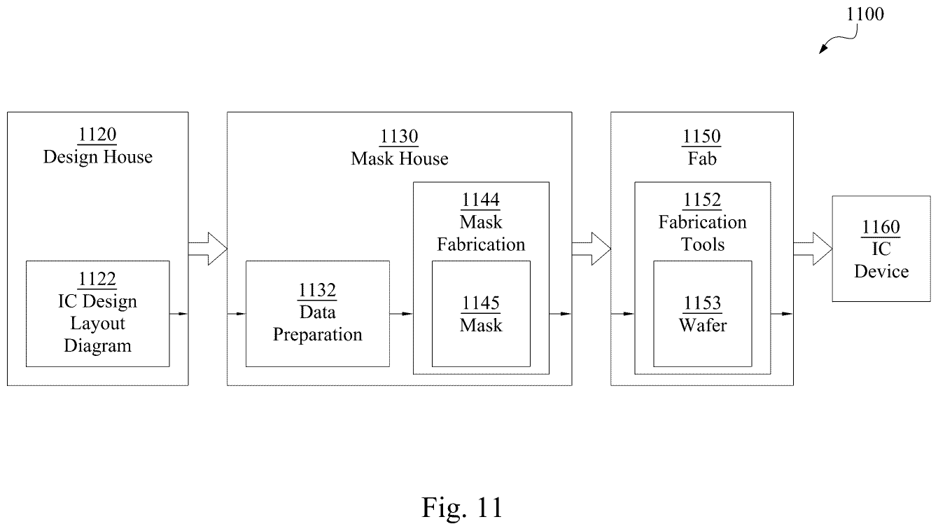

FIG. 8 is a flowchart of a method 800 of generating a layout plan for a semiconductor die, in accordance with some embodiments. In some embodiments, the semiconductor die based on method 800 corresponds to semiconductor die 710 in FIG. 7A or semiconductor die 720 in FIG. 7B, in view of various configurations in the examples of FIGS. 1-6B. In some embodiments, various operations of method 800 are performed by an EDA system as discussed with respect to the EDA system in FIG. 10. In some embodiments, method 800 is usable in conjunction with an IC manufacturing system as discussed with respect to the IC manufacturing system 1100 in FIG. 11. Method 800 includes blocks 810-830.

At block 810, a word line driver layout cell of the layout plan is formed. The word line driver layout cell is indicative of a word line driver (e.g., word line driver 352 in FIG. 3B) in a driver area (e.g., word line driver area 314 in FIG. 3B) of the semiconductor die.

At block 820, a set of conductive patterns and via patterns of the layout plan are formed. The set of conductive patterns and via patterns is indicative of a set of conductive paths of the semiconductor die (e.g., the metallization layers and the corresponding via structures in FIG. 2) that electrically couples the word line driver to a first word line (e.g., word line 354 in FIG. 3B) and a second word line (e.g., word line 356 in FIG. 3B). In some embodiments, a memory device that is formed based on the semiconductor die includes a first memory cell array (e.g., half memory array in memory cell array area 342 in FIG. 3A or half memory array in a memory cell array area indicated by tag 342′ in FIG. 3B) that includes a first plurality of memory cells electrically coupled to the first word line; and a second memory cell array (e.g., half memory array in memory cell array area 343 in FIG. 3A or half memory array in a memory cell array area indicated by tag 343′ in FIG. 3B) that includes a second plurality of memory cells electrically coupled to the second word line.

In some embodiments, method 800 further includes forming a first word line pattern of the layout plan indicative of the first word line that is in a first area (e.g., memory cell array area 342 in FIG. 3A) of the semiconductor die and electrically coupled to the first plurality of memory cells of the first memory cell array in the first area; and forming a second word line pattern of the layout plan indicative of the second word line that is in a second area (e.g., memory cell array area 343 in FIG. 3A) of the semiconductor die and electrically coupled to the second plurality of memory cells of the second memory cell array in the second area. In some embodiments, the first area (e.g., memory cell array area 342 in FIG. 3A) and the second area (e.g., memory cell array area 343 in FIG. 3A) of the semiconductor die are adjacent to each other and at least partially overlap the driver area (e.g., word line driver area 314 in FIG. 3B) of the semiconductor die.

In some embodiments, method 800 further includes forming a first plurality of bit line patterns of the layout plan indicative of a first plurality of bit lines in the first area of the semiconductor die, the first plurality of memory cells being electrically coupled to corresponding ones of the first plurality of bit lines; and forming a second plurality of bit line patterns of the layout plan indicative of a second plurality of bit lines in the second area of the semiconductor die, the second plurality of memory cells being electrically coupled to corresponding ones of the second plurality of bit lines. In some embodiments, method 800 further includes forming a first plurality of sense amplifier layout cells of the layout plan indicative of a first plurality of sense amplifiers in a first sense amplifier area (e.g., sense amplifier area 332 in FIG. 3B) of the semiconductor die and electrically coupled to the first plurality of bit lines; and forming a second plurality of sense amplifier layout cells of the layout plan indicative of a second plurality of sense amplifiers in a second sense amplifier area (e.g., sense amplifier area 333 in FIG. 3B) of the semiconductor die and electrically coupled to the second plurality of bit lines.

In some embodiments, method 800 further includes forming a third word line pattern of the layout plan indicative of a third word line (e.g., word line 366 in FIG. 3B) that is in a third area (e.g., memory cell array area 341 in FIG. 3A) of the semiconductor die electrically coupled to a third plurality of memory cells (e.g., half memory array in memory cell array area 341 in FIG. 3A or half memory array in a memory cell array indicated by tag 341′ in FIG. 3B) of the first memory cell array in the third area. In some embodiments, method 800 further includes forming a second word line driver layout cell of the layout plan indicative of a second word line driver (e.g., word line driver 362 in FIG. 3B) in a second driver area (e.g., word line driver area 312 in FIG. 3B) of the semiconductor die; and forming a second set of conductive patterns and via patterns of the layout plan indicative of a second set of conductive paths electrically coupling the second word line driver and the third word line.

In some embodiments, method 800 further includes forming a dummy word line pattern of the layout plan indicative of a dummy word line (e.g., word line 364 in FIG. 3B) that is in a fourth area (e.g., dummy area 347 in FIG. 3A) of the semiconductor die, the third area and the fourth area being adjacent to each other and at least partially overlapping the second driver area. In some embodiments, the second set of conductive patterns and via patterns is indicative of the second set of conductive paths that further electrically couples the dummy word line to the second word line driver and the third word line.

In some embodiments, method 800 further includes forming a fourth word line pattern of the layout plan indicative of a fourth word line (e.g., word line 424 in FIG. 4, with first word line and second word line corresponding to word lines 414 and 416 in FIG. 4) that is in a fifth area (e.g., memory cell array area 344 in FIG. 3A or a memory cell array area indicated by tag 344′ in FIG. 4) of the semiconductor die electrically coupled to a fourth plurality of memory cells of a third memory cell array (e.g., half memory array in in memory cell array area 344 in FIG. 3A or half memory array in a memory cell array area indicated by tag 344′ in FIG. 4) in the fifth area. In some embodiments, the fifth area is different from the first area (e.g., memory cell array area 342 in FIG. 3A or a memory cell array area indicated by tag 342′ in FIG. 4), the second area (e.g., memory cell array area 343 in FIG. 3A or a memory cell array area indicated by tag 343′ in FIG. 4), and the driver area (e.g., word line driver area 314 in FIG. 4). In some embodiments, the set of conductive patterns and via patterns is indicative of the set of conductive paths that further electrically couples the fourth word line to the word line driver, the first word line, and the second word line.

In some embodiments, method 800 further includes forming memory layout cells of the layout plan corresponding to the first memory cell array and the second memory cell array that are in a BEOL portion of the semiconductor die.

At block 830, the layout plan of the semiconductor die, with inclusion of at least the word line driver layout cell from block 810 and the set of conductive patterns and via patterns from block 820, is stored in a memory of a processing device (e.g., storage medium 1004 of the EDA system in FIG. 10).

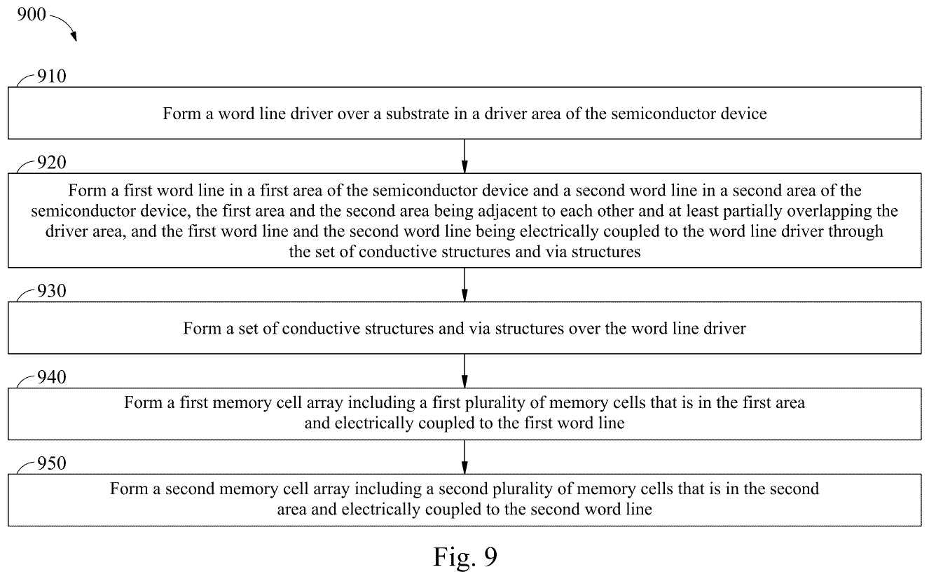

FIG. 9 is a flowchart of a method 900 of manufacturing a semiconductor device, in accordance with some embodiments. In some embodiments, the semiconductor device manufactured based on method 900 corresponds to memory device 200 in FIG. 2, memory device 700A in FIG. 7A, or memory device 700B in FIG. 7B, in view of various configurations in the examples of FIGS. 1-6B. In some embodiments, method 900 is usable in conjunction with an IC manufacturing system as discussed with respect to the IC manufacturing system 1100 in FIG. 11. Method 900 includes blocks 910-950.

At block 910, a word line driver (e.g., word line driver 352 in FIG. 3B) is formed over a substrate of the semiconductor device in a driver area (e.g., word line driver area 314 in FIG. 3B) of the semiconductor device.

At block 920, a set of conductive structures and via structures (e.g., the metallization layers and the corresponding via structures in FIG. 2) is formed over the word line driver.

At block 930, a first word line (e.g., word line 354 in FIG. 3B) is formed in a first area (e.g., memory cell array area 342 in FIG. 3A or a memory cell array area indicated by tag 342′ in FIG. 3B) of the semiconductor device. Also, a second word line (e.g., word line 356 in FIG. 3B) is formed in a second area (e.g., memory cell array area 343 in FIG. 3A or a memory cell array area indicated by tag 343′ in FIG. 3B) of the semiconductor device. In some embodiments, the first area and the second area are adjacent to each other and at least partially overlapping the driver area (e.g., word line driver area 314 in FIG. 3B). In some embodiments, the first word line and the second word line are electrically coupled to the word line driver through the set of conductive structures and via structures.

At block 940, a first memory cell array is formed. In some embodiments, the first memory cell array includes a first plurality of memory cells that is in the first area and electrically coupled to the first word line.

At block 950, a second memory cell array is formed. In some embodiments, the second memory cell array includes a second plurality of memory cells that is in the second area and electrically coupled to the second word line.

In some embodiments, method 900 further includes forming a first plurality of bit lines in the first area of the semiconductor device (e.g., bit lines in memory cell array area 342 in FIG. 3A or a memory cell array area indicated by tag 342′ in FIG. 3B in view of the examples in FIGS. 1 and 2), where the first plurality of memory cells is electrically coupled to corresponding ones of the first plurality of bit lines. In some embodiments, method 900 further includes forming a second plurality of bit lines in the second area of the semiconductor device (e.g., bit lines in memory cell array area 343 in FIG. 3A or a memory cell array area indicated by tag 343′ in FIG. 3B in view of the examples in FIGS. 1 and 2), where the second plurality of memory cells is electrically coupled to corresponding ones of the second plurality of bit lines. In some embodiments, method 900 further includes forming a first plurality of sense amplifiers in a first area sense amplifier of the semiconductor device and electrically coupled to the first plurality of bit lines, and forming a second plurality of sense amplifiers in a second sense amplifier area of the semiconductor device and electrically coupled to the second plurality of bit lines (e.g., sense amplifiers in sense amplifier areas 332 and 333 in view of the examples in FIGS. 1 and 2).

In some embodiments, the first memory cell array further includes a third plurality of memory cells that is in a third area of the semiconductor device adjacent to the first area the semiconductor device (e.g., half memory array in memory cell array area 341 in FIG. 3A or half memory array in a memory cell array indicated by tag 341′ in FIG. 3B). In some embodiments, method 900 further includes forming a second word line driver (e.g., word line driver 362 in FIG. 3B) in a second driver area (e.g., word line driver area 312 in FIG. 3B) of the semiconductor device, where the third area at least partially overlaps the second driver area. In some embodiments, method 900 further includes forming a third word line (e.g., word line 366 in FIG. 3B) in the third area of the semiconductor device and electrically coupled to the third plurality of memory cells of the first memory cell array, and forming a second set of conductive structures and via structures electrically coupling the second word line driver and the third word line.

In some embodiments, method 900 further includes forming a dummy word line (e.g., word line 364 in FIG. 3B) in a fourth area of the semiconductor device (e.g., dummy area 347 in FIG. 3A). In some embodiments, the third area and the fourth area are adjacent to each other and at least partially overlap the second driver area. In some embodiments, the dummy word line is electrically coupled to the second word line driver and the third word line through the second set of conductive paths.

In some embodiments, method 900 further includes forming a fourth word line (e.g., word line 424 in FIG. 4, with first word line and second word line corresponding to word lines 414 and 416 in FIG. 4) in a fifth area of the semiconductor device (e.g., memory cell array area 344 in FIG. 3A or a memory cell array area indicated by tag 344′ in FIG. 4), and forming a third memory cell array including a third plurality of memory cells (e.g., half memory array in in memory cell array area 344 in FIG. 3A or half memory array in a memory cell array area indicated by tag 344′ in FIG. 4) that is in the fifth area of the semiconductor device and electrically coupled to the fourth word line. In some embodiments, the word line driver, the fourth word line, the first word line, and the second word line are electrically coupled together through the set of conductive structures and via structures.

FIG. 10 is a block diagram of an electronic design automation (EDA) system 1000 in accordance with some embodiments. In some embodiments, EDA system 1000 includes an automatic placement and routing (APR) system. Methods described herein in accordance with one or more embodiments are implementable, for example, using EDA system 1000, in accordance with some embodiments.

In some embodiments, EDA system 1000 is a general-purpose computing device including a hardware processor 1002 and a computer-readable storage medium 1004. Storage medium 1004, amongst other things, is encoded with, i.e., stores, computer program code 1006, i.e., a set of executable instructions. Execution of instructions 1006 by hardware processor 1002 represents (at least in part) an EDA tool which implements a portion or all of the methods described herein in accordance with one or more embodiments (hereinafter, the noted processes and/or methods).

Processor 1002 is electrically coupled to computer-readable storage medium 1004 via a bus 1008. Processor 1002 is also electrically coupled to an I/O interface 1010 by bus 1008. A network interface 1012 is also electrically connected to processor 1002 via bus 1008. Network interface 1012 is connected to a network 1014, so that processor 1002 and computer-readable storage medium 1004 are capable of connecting to external elements via network 1014. Processor 1002 is configured to execute computer program code 1006 encoded in computer-readable storage medium 1004 in order to cause system 1000 to be usable for performing a portion or all of the noted processes and/or methods. In one or more embodiments, processor 1002 is a CPU, a multi-processor, a distributed processing system, an application specific integrated circuit (ASIC), and/or a suitable processing unit.

In one or more embodiments, computer-readable storage medium 1004 is a non-transitory computer-readable storage medium including an electronic, magnetic, optical, electromagnetic, infrared, and/or a semiconductor system (or apparatus or device). For example, computer-readable storage medium 1004 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1004 includes a compact disk-read only memory (CD-ROM), a compact disk-read/write (CD-R/W), and/or a digital video disc (DVD).

In one or more embodiments, storage medium 1004 stores computer program code 1006 configured to cause system 1000 (where such execution represents (at least in part) the EDA tool) to be usable for performing a portion or all of the noted processes and/or methods. In one or more embodiments, storage medium 1004 also stores information which facilitates performing a portion or all of the noted processes and/or methods. In one or more embodiments, storage medium 1004 stores a cell library 1007 of standard cells including such standard cells as disclosed herein. In one or more embodiments, storage medium 1004 stores one or more layout plans 1009 corresponding to one or more layouts plans disclosed herein.

EDA system 1000 includes I/O interface 1010. I/O interface 1010 is coupled to external circuitry. In one or more embodiments, I/O interface 1010 includes a keyboard, keypad, mouse, trackball, trackpad, touchscreen, and/or cursor direction keys for communicating information and commands to processor 1002.

EDA system 1000 also includes network interface 1012 coupled to processor 1002. Network interface 1012 allows system 1000 to communicate with network 1014, to which one or more other computer systems are connected. Network interface 1012 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1000.

System 1000 is configured to receive information through I/O interface 1010. The information received through I/O interface 1010 includes one or more of instructions, data, design rules, libraries of standard cells, and/or other parameters for processing by processor 1002. The information is transferred to processor 1002 via bus 1008. EDA system 1000 is configured to receive information related to a UI through I/O interface 1010. The information is stored in computer-readable medium 1004 as user interface (UI) 1042.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1000. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 11 is a block diagram of an IC manufacturing system 1100, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1100.

In FIG. 11, IC manufacturing system 1100 includes entities, such as a design house 1120, a mask house 1130, and an IC manufacturer/fabricator (fab) 1150, that interact with one another in the design, development, and manufacturing cycles and/or services related to manufacturing an IC device 1160. The entities in system 1100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1120, mask house 1130, and IC fab 1150 is owned by a single larger company. In some embodiments, two or more of design house 1120, mask house 1130, and IC fab 1150 coexist in a common facility and use common resources.

Design house (or design team) 1120 generates an IC design layout diagram 1122 (e.g., a layout plan). IC design layout diagram 1122 includes various geometrical patterns designed for an IC device 1160. The geometrical patterns correspond to patterns of metal, oxide, or semiconductor layers that make up the various components of IC device 1160 to be fabricated. The various layers combine to form various IC features. For example, a portion of IC design layout diagram 1122 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1120 implements a proper design procedure to form IC design layout diagram 1122. The design procedure includes one or more of logic design, physical design or place and route. IC design layout diagram 1122 is presented in one or more data files having information of the geometrical patterns. For example, IC design layout diagram 1122 can be expressed in a GDSII file format or DFII file format.

Mask house 1130 includes data preparation 1132 and mask fabrication 1144. Mask house 1130 uses IC design layout diagram 1122 to manufacture one or more masks 1145 to be used for fabricating the various layers of IC device 1160 according to IC design layout diagram 1122. Mask house 1130 performs mask data preparation 1132, where IC design layout diagram 1122 is translated into a representative data file (RDF). Mask data preparation 1132 provides the RDF to mask fabrication 1144. Mask fabrication 1144 includes a mask writer. A mask writer converts the RDF to an image on a substrate, such as a mask (reticle) 1145 or a semiconductor wafer 1153. The design layout diagram 1122 is manipulated by mask data preparation 1132 to comply with particular characteristics of the mask writer and/or requirements of IC fab 1150. In FIG. 11, mask data preparation 1132 and mask fabrication 1144 are illustrated as separate elements. In some embodiments, mask data preparation 1132 and mask fabrication 1144 can be collectively referred to as mask data preparation.

In some embodiments, mask data preparation 1132 includes optical proximity correction (OPC) which uses lithography enhancement techniques to compensate for image errors, such as those that can arise from diffraction, interference, other process effects and the like. OPC adjusts IC design layout diagram 1122. In some embodiments, mask data preparation 1132 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1132 includes a mask rule checker (MRC) that checks the IC design layout diagram 1122 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1122 to compensate for photolithographic implementation effects during mask fabrication 1144, which may undo part of the modifications performed by OPC in order to meet mask creation rules.

In some embodiments, mask data preparation 1132 includes lithography process checking (LPC) that simulates processing that will be implemented by IC fab 1150 to fabricate IC device 1160. LPC simulates this processing based on IC design layout diagram 1122 to create a simulated manufactured device, such as IC device 1160. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1122.

It should be understood that the above description of mask data preparation 1132 has been simplified for the purposes of clarity. In some embodiments, data preparation 1132 includes additional features such as a logic operation (LOP) to modify the IC design layout diagram 1122 according to manufacturing rules. Additionally, the processes applied to IC design layout diagram 1122 during data preparation 1132 may be executed in a variety of different orders.

After mask data preparation 1132 and during mask fabrication 1144, a mask 1145 or a group of masks 1145 are fabricated based on the modified IC design layout diagram 1122. In some embodiments, mask fabrication 1144 includes performing one or more lithographic exposures based on IC design layout diagram 1122. In some embodiments, an electron-beam (e-beam) or a mechanism of multiple e-beams is used to form a pattern on a mask (photomask or reticle) 1145 based on the modified IC design layout diagram 1122. Mask 1145 can be formed in various technologies. In some embodiments, mask 1145 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1145 includes a transparent substrate (e.g., fused quartz) and an opaque material (e.g., chromium) coated in the opaque regions of the binary mask. In another example, mask 1145 is formed using a phase shift technology. In a phase shift mask (PSM) version of mask 1145, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1144 is used in a variety of processes. For example, such a mask(s) is used in an ion implantation process to form various doped regions in semiconductor wafer 1153, in an etching process to form various etching regions in semiconductor wafer 1153, and/or in other suitable processes.

IC fab 1150 is an IC fabrication business that includes one or more manufacturing facilities for the fabrication of a variety of different IC products. In some embodiments, IC fab 1150 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1150 includes fabrication tools 1152 configured to execute various manufacturing operations on semiconductor wafer 1153 such that IC device 1160 is fabricated in accordance with the mask(s), e.g., mask 1145. In various embodiments, fabrication tools 1152 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1150 uses mask(s) 1145 fabricated by mask house 1130 to fabricate IC device 1160. Thus, IC fab 1150 at least indirectly uses IC design layout diagram 1122 to fabricate IC device 1160. In some embodiments, semiconductor wafer 1153 is fabricated by IC fab 1150 using mask(s) 1145 to form IC device 1160. In some embodiments, the IC fabrication includes performing one or more lithographic exposures based at least indirectly on IC design layout diagram 1122. Semiconductor wafer 1153 includes a silicon substrate or other proper substrate having material layers formed thereon. Semiconductor wafer 1153 further includes one or more of various doped regions, dielectric features, multilevel interconnects, and the like (formed at subsequent manufacturing steps).

In one aspect, a memory device includes a FEOL portion that includes a word line driver configured to output a word line signal to a first word line and a second word line, and a memory cell portion over the FEOL portion. The memory cell portion includes memory cells accessible as at least two memory cell arrays, including a first memory cell array that includes a first plurality of memory cells electrically coupled to the first word line, and a second memory cell array that includes a second plurality of memory cells electrically coupled to the second word line.

In one aspect, semiconductor device includes a substrate, a word line driver over the substrate in a driver area of the semiconductor device, a set of conductive structures and via structures over the word line driver, and a first word line in a first area of the semiconductor device and a second word line in a second area of the semiconductor device. The first area and the second area are adjacent to each other and at least partially overlapping the driver area, and the first word line and the second word line are electrically coupled to the word line driver through the set of conductive structures and via structures. The semiconductor device further includes a first memory cell array including a first plurality of memory cells that is in the first area and electrically coupled to the first word line, and a second memory cell array including a second plurality of memory cells that is in the second area and electrically coupled to the second word line.

In one aspect, a method of manufacturing a semiconductor device includes forming a word line driver over a substrate in a driver area of the semiconductor device, forming a set of conductive structures and via structures over the word line driver, and forming a first word line in a first area of the semiconductor device and a second word line in a second area of the semiconductor device. The first area and the second area are adjacent to each other and at least partially overlapping the driver area, and the first word line and the second word line are electrically coupled to the word line driver through the set of conductive structures and via structures. The method further includes forming a first memory cell array including a first plurality of memory cells that is in the first area and electrically coupled to the first word line, and forming a second memory cell array including a second plurality of memory cells that is in the second area and electrically coupled to the second word line.

In one aspect, a method of generating a layout plan for a semiconductor die includes forming a word line driver layout cell of the layout plan indicative of a word line driver in a driver area of the semiconductor die and forming a set of conductive patterns and via patterns of the layout plan indicative of a set of conductive paths of the semiconductor die that electrically couples the word line driver to a first word line and a second word line. A memory device that is formed based on the semiconductor die includes a first memory cell array that includes a first plurality of memory cells electrically coupled to the first word line, and a second memory cell array that includes a second plurality of memory cells electrically coupled to the second word line. The method further includes storing the layout plan in a storage device of a processing device.

In one aspect, a processing device includes a storage device and processing circuitry coupled to the storage device and configured to form a word line driver layout cell of a layout plan of a semiconductor die indicative of a word line driver in a driver area of the semiconductor die, and form a set of conductive patterns and via patterns of the layout plan indicative of a set of conductive paths of the semiconductor die that electrically couples the word line driver to a first word line and a second word line. A memory device that is formed based on the semiconductor die includes a first memory cell array that includes a first plurality of memory cells electrically coupled to the first word line, and a second memory cell array that includes a second plurality of memory cells electrically coupled to the second word line. The processing device is further configured to store the layout plan in the storage device of the processing device.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A memory device, comprising:
a front-end-of-line (FEOL) portion that includes
a word line driver configured to output a word line signal to a first word line and a second word line; and
a memory cell portion over the FEOL portion, the memory cell portion including memory cells accessible as at least two memory cell arrays, including
a first memory cell array that includes a first plurality of memory cells electrically coupled to the first word line, and
a second memory cell array that includes a second plurality of memory cells electrically coupled to the second word line.

2. The memory device of claim 1, wherein
the FEOL portion further comprises:
a first plurality of sense amplifiers electrically coupled to a first plurality of bit lines; and
a second plurality of sense amplifiers electrically coupled to a second plurality of bit lines,
the first plurality of memory cells is electrically coupled to corresponding ones of the first plurality of bit lines, and
the second plurality of memory cells is electrically coupled to corresponding ones of the second plurality of bit lines.

3. The memory device of claim 1, wherein
the FEOL portion further includes
a second word line driver configured to output a second word line signal to a third word line, and
a third plurality of sense amplifiers electrically coupled to a third plurality of bit lines, and
the first memory cell array further includes a third plurality of memory cells electrically coupled to the third word line and corresponding ones of the third plurality of bit lines.

4. The memory device of claim 3, wherein
the second word line driver is further configured to output the second word line signal to a dummy word line.

5. The memory device of claim 1, wherein
the word line driver is further configured to output the word line signal to a fourth word line,
the FEOL portion further includes
a fourth plurality of sense amplifiers electrically coupled to a fourth plurality of bit lines, and
the at least two memory cell arrays of the memory cell portion further include
a third memory cell array that includes a fourth plurality of memory cells electrically coupled to the fourth word line and corresponding ones of the fourth plurality of bit lines.

6. The memory device of claim 1, wherein the first memory cell array and the second memory cell array include memory cells corresponding to
volatile memory cells including dynamic random access memory (DRAM) cells or static random access memory (SRAM) cells, or
non-volatile memory cells including floating-gate memory cells, ferroelectric random access memory (FRAM) cells, magnetic random access memory (MRAM) cells, phase-change memory (PCM) cells, or resistive random access memory (RRAM) cells.

7. The memory device of claim 1, wherein
the front-end-of-line (FEOL) portion is part of a semiconductor die, and
the memory cell portion is included in a back-end-of-line (BEOL) portion of the semiconductor die.

8. The memory device of claim 1, wherein
the front-end-of-line (FEOL) portion is part of a first semiconductor die, and
the memory cell portion is included in a second semiconductor die.

9. A semiconductor device, comprising:
a substrate;
a word line driver over the substrate in a driver area of the semiconductor device;
a set of conductive structures and via structures over the word line driver;
a first word line in a first area of the semiconductor device and a second word line in a second area of the semiconductor device, the first area and the second area being adjacent to each other and at least partially overlapping the driver area, and the first word line and the second word line being electrically coupled to the word line driver through the set of conductive structures and via structures;
a first memory cell array including a first plurality of memory cells that is in the first area and electrically coupled to the first word line; and
a second memory cell array including a second plurality of memory cells that is in the second area and electrically coupled to the second word line.

10. The semiconductor device of claim 9, further comprising:
a first plurality of bit lines in the first area of the semiconductor device, the first plurality of memory cells being electrically coupled to corresponding ones of the first plurality of bit lines;
a second plurality of bit lines in the second area of the semiconductor device, the second plurality of memory cells being electrically coupled to corresponding ones of the second plurality of bit lines;
a first plurality of sense amplifiers in a first sense amplifier area of the semiconductor device and electrically coupled to the first plurality of bit lines; and
a second plurality of sense amplifiers in a second sense amplifier area of the semiconductor device and electrically coupled to the second plurality of bit lines.

11. The semiconductor device of claim 10, wherein
the first memory cell array further includes a third plurality of memory cells that is in a third area of the semiconductor device adjacent to the first area the semiconductor device;
the semiconductor device further comprises:
a second word line driver in a second driver area of the semiconductor device, the third area at least partially overlapping the second driver area;
a third word line in the third area of the semiconductor device and electrically coupled to the third plurality of memory cells of the first memory cell array; and
a second set of conductive structures and via structures electrically coupling the second word line driver and the third word line.

12. The semiconductor device of claim 11, further comprising:
a dummy word line in a fourth area of the semiconductor device, the third area and the fourth area being adjacent to each other and at least partially overlapping the second driver area, and the dummy word line being electrically coupled to the second word line driver and the third word line through the second set of conductive structures and via structures.

13. The semiconductor device of claim 10, further comprising:
a fourth word line in a fifth area of the semiconductor device; and
a third memory cell array including a third plurality of memory cells that is in the fifth area of the semiconductor device and electrically coupled to the fourth word line,
wherein
the word line driver, the fourth word line, the first word line, and the second word line are electrically coupled together through the set of conductive structures and via structures.

14. The semiconductor device of claim 9, comprising:
a semiconductor die that includes
a front-end-of-line (FEOL) portion including the word line driver, and
a back-end-of-line (BEOL) portion including the first memory cell array and the second memory cell array.

15. The semiconductor device of claim 9, comprising:
a first semiconductor die that includes a front-end-of-line (FEOL) portion including the word line driver, and
a second semiconductor die that includes the first memory cell array and the second memory cell array.

16. A method of manufacturing a semiconductor device, comprising:
forming a word line driver over a substrate in a driver area of the semiconductor device;
forming a set of conductive structures and via structures over the word line driver;
forming a first word line in a first area of the semiconductor device and a second word line in a second area of the semiconductor device, the first area and the second area being adjacent to each other and at least partially overlapping the driver area, and the first word line and the second word line being electrically coupled to the word line driver through the set of conductive structures and via structures;
forming a first memory cell array including a first plurality of memory cells that is in the first area and electrically coupled to the first word line; and
forming a second memory cell array including a second plurality of memory cells that is in the second area and electrically coupled to the second word line.

17. The method of claim 16, further comprising:
forming a first plurality of bit lines in the first area of the semiconductor device, the first plurality of memory cells being electrically coupled to corresponding ones of the first plurality of bit lines;
forming a second plurality of bit lines in the second area of the semiconductor device, the second plurality of memory cells being electrically coupled to corresponding ones of the second plurality of bit lines;
forming a first plurality of sense amplifiers in a first sense amplifier area of the semiconductor device and electrically coupled to the first plurality of bit lines; and
forming a second plurality of sense amplifiers in a second sense amplifier area of the semiconductor device and electrically coupled to the second plurality of bit lines.

18. The method of claim 17, wherein
the first memory cell array further includes a third plurality of memory cells that is in a third area of the semiconductor device adjacent to the first area the semiconductor device;
the method further comprises:
forming a second word line driver in a second driver area of the semiconductor device, the third area at least partially overlapping the second driver area;
forming a third word line in the third area of the semiconductor device and electrically coupled to the third plurality of memory cells of the first memory cell array; and
forming a second set of conductive structures and via structures electrically coupling the second word line driver and the third word line.

19. The method of claim 18, further comprising:
forming a dummy word line in a fourth area of the semiconductor device, the third area and the fourth area being adjacent to each other and at least partially overlapping the second driver area, and the dummy word line being electrically coupled to the second word line driver and the third word line through the second set of conductive structures and via structures.

20. The method of claim 17, further comprising:
forming a fourth word line in a fifth area of the semiconductor device; and
forming a third memory cell array including a third plurality of memory cells that is in the fifth area of the semiconductor device and electrically coupled to the fourth word line,
wherein
the word line driver, the fourth word line, the first word line, and the second word line are electrically coupled together through the set of conductive structures and via structures.
